(19) United States
(12) Patent Application Publication
(10) Pub. No.: US 2022/0271131 A1
(43) Pub. Date: Aug. 25, 2022

(54) SEMICONDUCTOR STRUCTURE AND METHOD FOR FORMING SAME

(71) Applicant: CHANGXIN MEMORY TECHNOLOGIES, INC., Hefei City (CN)

(72) Inventors: Lianhong WANG, Hefei (CN); Xingsong SU, Hefei (CN)

(21) Appl. No.: 17/568,963

(22) Filed: Jan. 5, 2022

Related U.S. Application Data
(63) Continuation of application No. PCT/CN2021/112079, filed on Aug. 11, 2021.

(30) Foreign Application Priority Data
Feb. 23, 2021 (CN) 202110204335.5

(51) Int. Cl. H01L 29/40; H01L 29/423; H01L 27/108

(52) U.S. Cl. CPC H01L 29/401; H01L 29/4236; H01L 27/10888; H01L 27/10805

(57) ABSTRACT

A method for forming a semiconductor structure includes: providing a substrate, grooves having a first depth being provided; forming a first gate oxide layer on side walls and a bottom surface of a groove, and a first gate conductive layer on a surface of the first gate oxide layer, the first gate oxide layer and the first gate conductive layer having a second depth which is less than the first depth; forming a second gate oxide layer on surfaces of the groove that are not covered by the first gate oxide layer, in a direction perpendicular to a side wall of the groove, an equivalent gate oxide thickness of the second gate oxide layer being greater than that of the first gate oxide layer; and forming a second gate conductive layer which fills up a recess surrounded by the second gate oxide layer and the first gate conductive layer.

### CROSS-REFERENCE TO RELATED APPLICATIONS

The present application is a continuation application of International Application No. PCT/CN2021/112079, filed on Aug. 11, 2021, which claims priority to Chinese Patent Application No. 202110204335.5, filed on Feb. 23, 2021. The disclosures of International Application No. PCT/CN2021/112079 and Chinese Patent Application No. 202110204335.5 are hereby incorporated by reference in their entireties.

### BACKGROUND

A Dynamic Random Access Memory (DRAM) is a semiconductor storage device commonly used in computers, and consists of many repeated storage cells. With the continuous evolution of a DRAM manufacturing process, an integration degree is continuously increased, and an element size is continuously miniaturized. As a result, a transistor leakage in a DRAM cell seriously affects the data retention time in the DRAM cell.

Gate-Induced Drain Leakage (GIDL) is one of the main causes of the transistor leakage in the DRAM cell, and the GIDL is a leakage current caused by a high electric field effect at the junction of a gate and a drain. With the continuous improvement of the integration degree in the DRAM manufacturing process, a gate oxide layer becomes thinner and thinner, and the GIDL is increased sharply.

### SUMMARY

Embodiments of the present disclosure relate to, but are not limited to, a semiconductor structure and a method for forming the same.

Embodiments of the present disclosure provide a method for forming a semiconductor structure, including the following operations. A substrate is provided, in which grooves are provided in the substrate, in which the grooves have a first depth. A first gate oxide layer is formed on side walls and a bottom surface of a groove, and a first gate conductive layer is formed on a surface of the first gate oxide layer, in which the first gate oxide layer and the first gate conductive layer have a second depth, in which the second depth is less than the first depth. A second gate oxide layer is formed on surfaces of the groove that are not covered by the first gate oxide layer, in which in a direction perpendicular to a side wall of the groove, an equivalent gate oxide thickness of the second gate oxide layer is greater than an equivalent gate oxide thickness of the first gate oxide layer. A second gate conductive layer is formed, in which the second gate conductive layer fills a recess surrounded by the second gate oxide layer and the first gate conductive layer.

Embodiments of the present disclosure further provide a semiconductor structure, including: a substrate, a first gate oxide layer, a first gate conductive layer, a second gate oxide layer, and a second gate conductive layer. Grooves are provided in the substrate, in which the grooves have a first depth. The first gate oxide layer is provided on side walls and a bottom surface of a groove, and the first gate conductive layer is provided on a surface of the first gate oxide layer, in which the first gate oxide layer and the first gate conductive layer have a second depth, the second depth is less than the first depth. The second gate oxide layer is located on the side walls, exposed by the first gate oxide layer, of the groove, in which in a direction perpendicular to a side wall of the groove, the equivalent gate oxide thickness of the second gate oxide layer is greater than the equivalent gate oxide thickness of the first gate oxide layer. The second gate conductive layer fills up a recess surrounded by the second gate oxide layer and the first gate conductive layer.

### BRIEF DESCRIPTION OF THE DRAWINGS

One or more embodiments are exemplarily described by corresponding pictures in the drawings. These exemplary descriptions do not constitute limitation to the embodiments. Unless otherwise stated, the pictures in the drawings do not constitute scale limitation.

FIG. 1 is a structure schematic diagram of a semiconductor structure.

FIG. 2-FIG. 9 are structure schematic diagrams corresponding to each step in a method for forming a semiconductor structure provided by an embodiment of the present disclosure.

FIG. 10-FIG. 15 are structure schematic diagrams corresponding to each step in a method for forming a semiconductor structure provided by another embodiment of the present disclosure.

FIG. 16 is a structure schematic diagram of a semiconductor structure provided by an embodiment of the present disclosure.

### DETAILED DESCRIPTION

It may be seen from the background that a semiconductor structure in a related technology has a problem of GIDL.

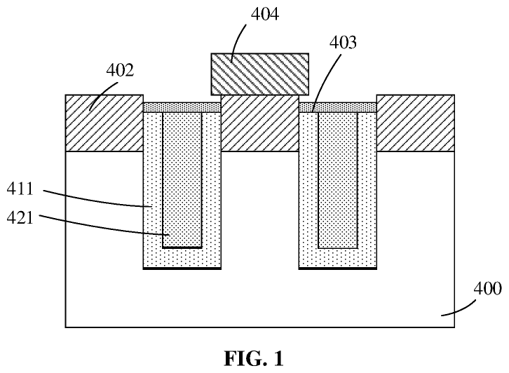

FIG. 1 is a structure schematic diagram of a semiconductor structure.

Referring to FIG. 1, the semiconductor structure includes a substrate 400, in which grooves and doped areas 402 are provided in the substrate 400. The doped areas 402 are located on two sides of the grooves. A gate oxide layer 411 is provided on a side wall and a bottom surface of a groove. A gate conductive layer 421 is provided on a surface of the gate oxide layer 411. A top surface of the gate oxide layer 411 and a top surface of the gate conductive layer 421 are covered with a protective layer 403. A bit line contact layer 404 is provided on a surface of a doped area 402 between adjacent protective layers 403, in which a bottom of the bit line contact layer 404 is higher than top surfaces of the protective layers 403.

When a gate is turned on, an enhanced electric field is generated in the area due to a depletion region generated in the gate. With the continuous increase of the integration degree in the DRAM manufacturing process, the thickness of the formed gate oxide layer 411 becomes smaller and smaller and the overall thickness of the gate oxide layers 411 is the same, resulting in that the band bending caused by the enhanced electric field easily penetrates the thinner gate oxide layer 411 to cause inter-band tunneling between the gate and the drain. In this case, there is a tunnel for a minority carrier moved in the gate to enter the drain, so that the GIDL is increased sharply, thereby affecting the performance of the semiconductor structure.

In order to solve the above problem, embodiments of the present disclosure provide a method for forming a semiconductor structure, with which the formed gate oxide layer includes two layers, in which an equivalent gate oxide thickness of a second gate oxide layer is greater than an equivalent gate oxide thickness of a first gate oxide layer. When the gate is turned on, an enhanced electric field is generated in the area due to a depletion region generated in the gate, but it is difficult for the band bending caused by the enhanced electric field to cause the inter-band tunneling between the gate and the drain because the equivalent gate oxide thickness of the second gate oxide layer is relatively thick. In this case, there is no tunnel for the minority carrier moved in the gate to enter the drain, so that a risk of generating the GIDL is reduced, thereby improving the performance of the semiconductor structure.

Each embodiment of the present disclosure is described in detail below in combination with the drawings. However, a person of ordinary skill in the art may understand that in each embodiment of the present disclosure, many technical details are proposed for a reader to better understand the present disclosure. However, even without these technical details and various changes and modifications based on the following embodiments, technical schemes claimed in the present disclosure may be achieved.

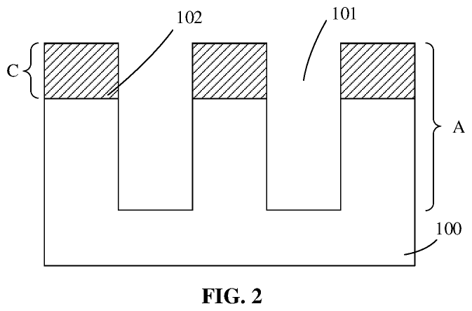

FIG. 2-FIG. 9 are structure schematic diagrams corresponding to each step in a method for forming a semiconductor structure provided by an embodiment of the present disclosure.

Referring to FIG. 2, a substrate 100 is provided, in which grooves 101 and doped areas 102 are provided in the substrate 100. The doped areas 102 are located on two sides of the grooves 101.

The doped areas 102 may be N-type doped areas or P-type doped areas. In the embodiment of the present disclosure, where the doped areas 102 are N-type doped areas, they are doped with N-type ions, and the substrate 100 is doped with P-type ions. In other embodiments, where the doped areas are P-type doped areas, they are doped with P-type ions, and the substrate is doped with N-type ions.

A doped area 102 located on one side of a groove 101 serves as a source, and a doped area 102 located on the other side of the groove 101 serves as a drain. The material of the substrate 100 is a semiconductor material. In the embodiment of the present disclosure, the material of the substrate 100 is silicon. In other embodiments, the substrate may also be a germanium substrate, a silicon germanium substrate, a silicon carbide substrate, or a silicon-on-insulator substrate.

The grooves 101 provide a process basis for subsequently forming gates, which are subsequently formed in the grooves 101.

The grooves 101 have a first depth A, and the doped areas 102 have a third depth C. Generally, the third depth C is less than the first depth A. The first depth A is a distance between a bottom portion of a groove 101 and the top surface of the substrate 100, and the third depth C is a distance between a bottom surface of a doped area 102 and the top surface of the substrate 100.

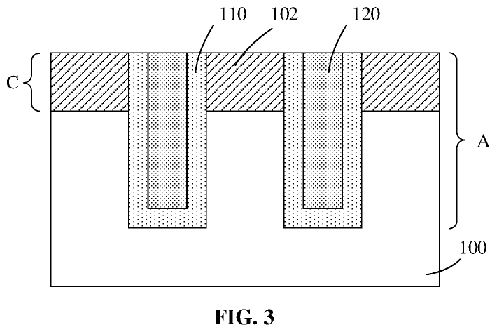

In some embodiments, the first depth A may be 300 nm-800 nm, for example, 400 nm, 500 nm, or 600 nm. The third depth C may be 100 nm-200 nm, for example, 120 nm, 150 nm or 180 nm. Referring to FIG. 3, an initial first gate oxide layer 110 is formed on side walls and a bottom surface of a groove 101 (referring to FIG. 2), in which the initial first gate oxide layer 110 completely covers the side walls of the groove 101.

In the embodiment of the present disclosure, a thermal oxidation process is used to form the initial first gate oxide layer 110. As the material of the substrate 100 is doped silicon, the initial first gate oxide layer 110 may be formed on the bottom surface and the side walls of the groove 101 by using a thermal oxidation process. In other embodiments, a chemical vapor deposition process may also be used to form the gate oxide layer.

In the embodiment of the present disclosure, in a direction perpendicular to the side wall of the groove 101, a thickness of the initial first gate oxide layer 110 formed by a thermal oxidation process may be between but not limited to 1 nm-10 nm, for example, 2 nm, 5 nm or 8 nm.

The material of the initial first gate oxide layer 110 may be silicon oxide or a high-dielectric material. The high-dielectric material includes ferroelectric ceramic materials, barium titanate-based materials, or lead titanate-based materials. The high-dielectric material refers to a material of which a relative dielectric constant is greater than that of silicon oxide, namely a high-k material.

In the embodiment of the present disclosure, the method for forming a semiconductor structure further includes the following operation. An initial first gate conductive layer 120 is formed on the surface of the initial first gate oxide layer 110, in which the initial first gate conductive layer 120 and the initial first gate oxide layer 110 fills up the groove 101.

The material of the initial first gate conductive layer 120 is metal, and the first gate conductive layer is subsequently formed on the basis of the initial first gate conductive layer 120. In the embodiment of the present disclosure, the material of the initial first gate conductive layer 120 may be tungsten. In other embodiments, the material of the gate conductive layer may also be copper, aluminum, gold, or silver and the like.

In the embodiment of the present disclosure, the chemical vapor deposition process is used to form the initial first gate conductive layer 120, in which a gas used to form the initial first gate conductive layer 120 made of tungsten includes silane and tungsten hexafluoride. In this way, when the initial first gate conductive layer 120 is formed, the initial first gate conductive layer 120 made of silane and tungsten hexafluoride has small crystal grains, so as to reduce the surface roughness of the initial first gate conductive layer 120, and thus improve the flatness of a top surface of the initial first gate conductive layer 120.

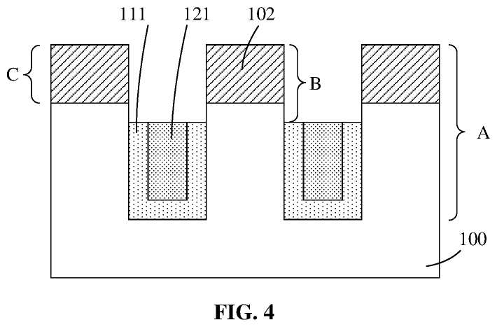

Referring to FIG. 4, the initial first gate oxide layer 110 and the initial first gate conductive layer 120 are etched back, so as to form a first gate oxide layer 111 on the side wall and the bottom surface of the groove 101, and a first gate conductive layer 121 on a surface of the first gate oxide layer 111. The first gate oxide layer 111 and the first gate conductive layer 121 have a second depth B.

The second depth B is a distance between a top surface of the first gate oxide layer 111 or a top surface of the first gate conductive layer 121 and the top surface of the substrate 100. In some embodiments, the second depth B may be 102 nm-230 nm.

The second depth B is less than the first depth A, and the second depth B is greater than or equal to the third depth C. It is equivalent to that in a horizontal direction, the bottom surface of the doped area 102 is higher than the top surface of the first gate oxide layer 111, and thus the side wall of the doped area 102 and the side wall of the first gate oxide layer 111 are not overlapped. Therefore, when the gate is turned on, an enhanced electric field is generated in the area due to a depletion region generated in the gate, which will not affect the doped area 102 after penetrating the first gate oxide layer 111, and thus inter-band tunneling will not occur between the doped area 102 and the first gate conductive layer 121.

The difference between the second depth B and the third depth c may be 2 nm-30 nm, for example, 5 nm, 10 nm or 20 nm. In this way, the side wall of the doped area 102 and the side wall of the first gate oxide layer 111 are not overlapped. When the gate is turned on, the range of the enhanced electric field generated in the area by the depletion region generated in the gate does not include an area in which the doped area 102 is located, so the enhanced electric field does not affect the doped area 102.

In a direction perpendicular to the side wall of the groove 101, the thickness of the first gate oxide layer 111 is 3 nm-10 nm, and it may be 5 nm, 7 nm or 9 nm.

In the direction perpendicular to the side wall of the groove 101, the thickness of the first gate conductive layer 121 is 30 nm-150 nm, for example, 60 nm, 90 nm or 120 nm.

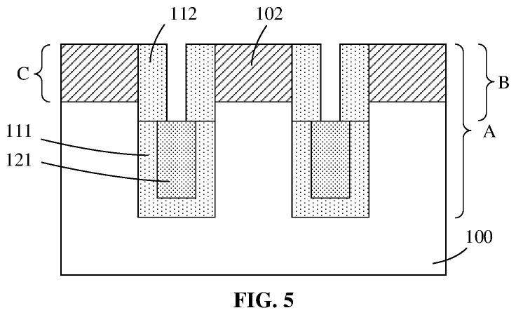

Referring to FIG. 5, an initial second gate oxide layer 112 is formed on the entire side wall, exposed by the first gate oxide layer 111, of the groove 101 (referring to FIG. 2).

The initial second gate oxide layer 112 serves as a basis for subsequently forming a second gate oxide layer, and the thickness of the initial second gate oxide layer 112 is greater than the thickness of the first gate oxide layer 111.

A thermal oxidation process is used to form the initial second gate oxide layer 112. As the material of the substrate 100 is doped silicon, the thermal oxidation process may be used to form the initial second gate oxide layer 112 on the side wall of the groove 101. In other embodiments, the chemical vapor deposition process may also be used to form the initial second gate oxide layer.

In the embodiment of the present disclosure, in the direction perpendicular to the groove 101, the thickness of the initial second gate oxide layer 112 formed by the thermal oxidation process may be between but not limited to 10 nm-15 nm. The thickness of the formed initial second gate oxide layer 112 is greater than the thickness of the initial first gate oxide layer 110.

In the embodiment of the present disclosure, the material of the initial second gate oxide layer 112 may be silicon oxide or a high-dielectric material. The high-dielectric material includes ferroelectric ceramic materials, barium titanate-based materials or lead titanate-based materials.

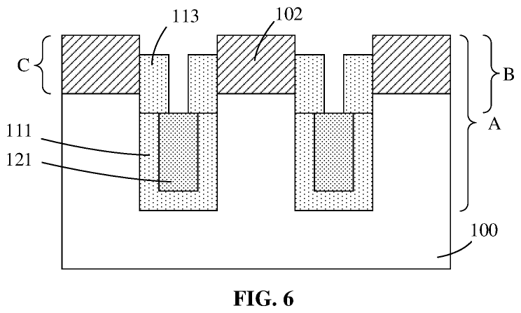

Referring to FIG. 6, a part of the initial second gate oxide layer 112 (referring to FIG. 5) that closes to a top of the groove 101 (referring to FIG. 2) is removed, so as to form the second gate oxide layer 113.

In the embodiment of the present disclosure, in the direction perpendicular to the side wall of the groove 101, the equivalent gate oxide thickness of the second gate oxide layer 113 is greater than the equivalent gate oxide thickness of the first gate oxide layer 111.

Because the second depth B is greater than or equal to the third depth C, in the horizontal direction, the doped area 102 is directly opposite to the second gate oxide layer 113. When the gate is turned on, an enhanced electric field is generated in the area due to a depletion region generated in the gate, an effective area of which includes an area in which the second gate oxide layer 113 is located. Moreover, because the equivalent gate oxide thickness of the second gate oxide layer 113 is relatively thick, the band bending caused by the enhanced electric field is not easy to cause the inter-band tunneling between the gate and the drain. In this case, there is on tunnel for a minority carrier moved in the gate to enter the drain, which is beneficial to reduce a risk of generating the GIDL, thereby improving the performance of the semiconductor structure.

In the embodiment of the present disclosure, the material of the second gate oxide layer 113 is the same as the material of the first gate oxide layer 111. In the direction perpendicular to the side wall of the groove 101, the thickness of the second gate oxide layer 113 is greater than the thickness of the first gate oxide layer 111.

Because the thickness of the second gate oxide layer 113 is greater than the thickness of the first gate oxide layer 111, the second gate oxide layer 113 is at least partially located on the top surface of the first gate conductive layer 121.

In other embodiments, the material of the second gate oxide layer is different from the material of the first gate oxide layer, and the dielectric constant of the material of the second gate oxide layer is greater than that of the material of the first gate oxide layer.

In the embodiment of the present disclosure, in the direction perpendicular to the side wall of the groove 101, the thickness of the second gate oxide layer 113 is 5 nm-20 nm, for example, 9 nm, 14 nm or 18 nm.

The third depth C is 2 nm-20 nm, for example 5 nm, 10 nm or 15 nm, greater than a distance between a top of the second gate oxide layer 113 and the top of the groove 101.

In a direction parallel to the side wall of the groove 101, the thickness of the second gate oxide layer 113 is 2 nm-20 nm, for example, 6 nm, 10 nm or 15 nm.

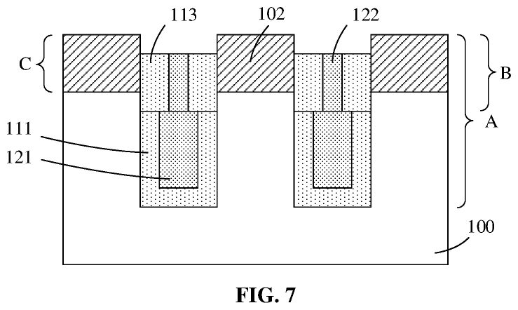

Referring to FIG. 7, the groove surrounded by the second gate oxide layer 113 and the first gate conductive layer 121 is filled up to form a second gate conductive layer 122.

In the embodiment of the present disclosure, the material of the second gate conductive layer 122 is polysilicon, a dielectric constant of which is greater than that of metal. The use of polysilicon as the second gate conductive layer 122 is more beneficial to regulate a gate voltage. In other embodiments, the material of the second gate conductive layer is metal.

In the embodiment of the present disclosure, in the direction perpendicular to the side wall of the groove 101 (referring to FIG. 2), the thickness of the second gate conductive layer 122 is 5 nm-100 nm, for example, 20 nm, 40 nm or 6 nm.

Because in the direction perpendicular to the side wall of the groove 101, the first gate oxide layer 111 and the first gate conductive layer 121 completely fill the groove 101, and the second gate oxide layer 113 and the second gate conductive layer 122 also completely fill the groove 101, the total thickness of the first gate oxide layer 111 and the first gate conductive layer 121 is the same as the total thickness of the second gate oxide layer 113 and the second gate conductive layer 122.

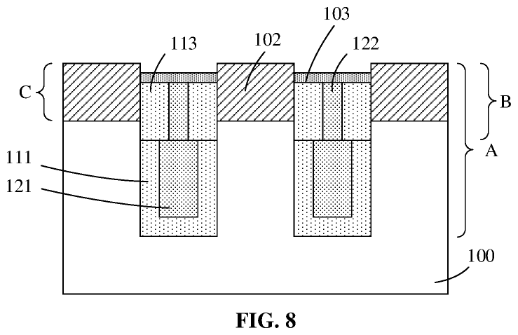

Referring to FIG. 8, a protective layer 103 is formed on top surfaces of the second gate oxide layer 113 and the second gate conductive layer 122.

The chemical vapor deposition process is used to form the protective layer 103. so that the protective layer 103 may be rapidly formed by deposition, and the formed protective layer 103 tightly covers, without forming any gap exposing the second gate oxide layer 113 or the second gate conductive layer 122. In other embodiments, an atomic layer deposition process may also be used to form the protective layer.

The top of the groove 101 (referring to FIG. 2) is above a top of the protective layer 103, which can prevent the protective layer 103 from contacting with the bit line contact layer and thus affecting the performance of the semiconductor structure as a bit line contact layer needs to be subsequently formed on the top of the substrate 100.

The material of the protective layer 103 is silicon nitride, which has an insulating effect.

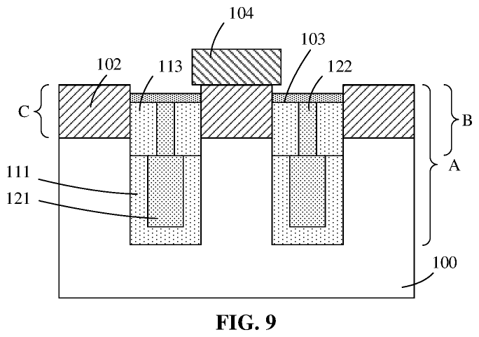

Referring to FIG. 9, after the protective layer 103 is formed, a bit line contact layer 104 is formed on the top surface of the substrate 100 between adjacent protective layers 103, in which the bottom of the bit line contact layer 104 keeps away from the top surfaces of the protective layers 103.

The bit line contact layer 104 may serve as an area for contacting a bit line to be formed subsequently.

In the method for forming a semiconductor structure provided by the embodiments of the present disclosure, the formed gate oxide layer includes two layers, in which the equivalent gate oxide thickness of the second gate oxide layer is greater than the equivalent gate oxide thickness of the first gate oxide layer, and the second depth of the first gate oxide layer is greater than or equal to the third depth of the doped area. When the gate is turned on, an enhanced electric field is generated in the area due to a depletion region generated in the gate, the effective area of which is located in the area in which the second gate oxide layer is located. and thus the band bending caused by which is not easy to cause the inter-band tunneling between the gate and the drain because the equivalent gate oxide thickness of the second gate oxide layer is relatively thick, and in the horizontal direction, the doped area is directly opposite to the second gate oxide layer. In this case, there is no tunnel for the minority carrier moved in the gate to enter the drain, which is beneficial to reduce the risk of generating the GIDL, thereby improving the performance of the semiconductor structure.

Another embodiment of the present disclosure provides a method for forming a semiconductor structure. The embodiment is approximately the same as the above embodiments, but the main difference is that in the embodiment of the present disclosure, a second gate conductive layer is firstly formed, and a second gate oxide layer is then formed. The method for forming a semiconductor structure provided by the another embodiment of the present disclosure is described in detail below in combination with the drawings, the same or corresponding parts as the above embodiments may refer to descriptions of the previous embodiments, and are not repeatedly described below.

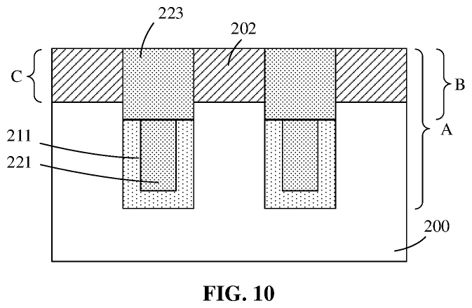

FIG. 10-FIG. 15 are structure schematic diagrams corresponding to each step in a method for forming a semiconductor structure provided by another embodiment of the present disclosure.

Referring to FIG. 10, in the embodiment of the present disclosure, a substrate 200 is provided, in which the substrate 200 is provided with grooves and doped areas 202, in which the grooves have a first depth A, and the doped areas 202 have a third depth C. A first gate oxide layer 211 and a first gate conductive layer 221 are formed in a groove, in which the first gate oxide layer 211 and the first gate conductive layer 221 have a second depth B. After the first gate conductive layer 221 is formed, an initial second gate conductive layer 223 for filling up the groove is formed.

In the embodiment of the present disclosure, a chemical vapor deposition process may be used to form the initial second gate conductive layer 223. The chemical vapor deposition process is fast in deposition rate, which saves production time and thus is beneficial to improve the production efficiency of the semiconductor structure.

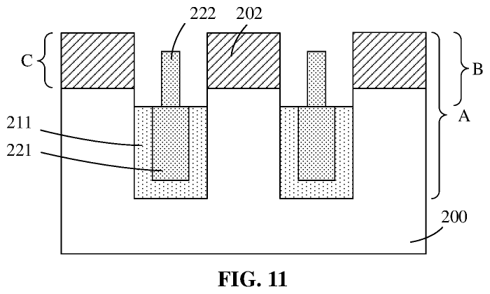

Referring to FIG. 11, the part of the initial second gate conductive layer 223 (referring to FIG. 10) at its top are removed and the part of the initial second gate conductive layer 223 located on side walls of the groove are removed to form gaps. In a direction perpendicular to the side walls of the groove, the thickness of the remaining initial second gate conductive layer 223 is less than the thickness of the first gate conductive layer 221, and the remaining initial second gate conductive layer 223 is a second gate conductive layer 222.

In the embodiment of the present disclosure, a part of the initial second gate conductive layer 223 at its top is firstly removed by a chemical mechanical polishing process, and then a part of the initial second gate conductive layer 223 located on the side walls of the groove is removed by a dry etching process, as to form the gaps.

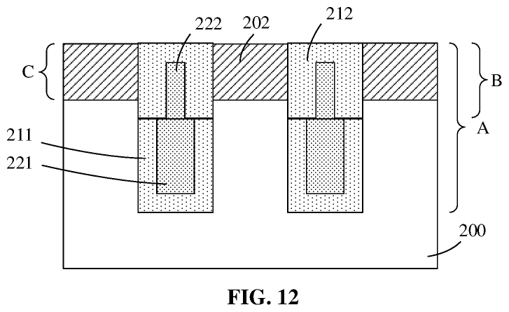

Referring to FIG. 12, an initial second gate oxide layer 212 for filling up the groove is formed.

In the embodiment of the present disclosure, the initial second gate oxide layer 212 is formed by a chemical vapor deposition process, by which the initial second gate oxide layer 212 for filling up the groove may be rapidly formed, and fully fills without leaving a gap.

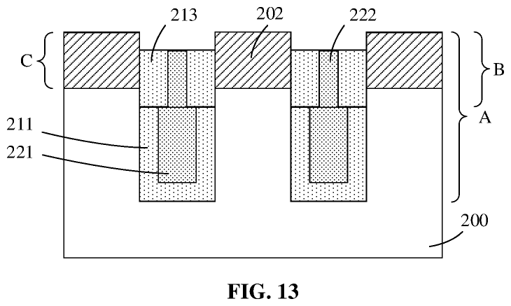

Referring to FIG. 13, a part of the initial second gate oxide layer 212 is removed, so that the top surface of the remaining initial second gate oxide layer 212 is flush with the top surface of the second gate conductive layer 222. The remaining initial second gate oxide layer 212 serves as the second gate oxide layer 213.

In the embodiment of the present disclosure, a chemical mechanical polishing process is used to remove the part of the initial second gate oxide layer 212 at its the top, so that not only the second gate oxide layer 213 of which the top is flush with the top of the second gate conductive layer 222 may be obtained, but also the top of the obtained second gate oxide layer 213 is flat, which is more beneficial to the close contact between the protective layer formed subsequently and the second gate oxide layer 213.

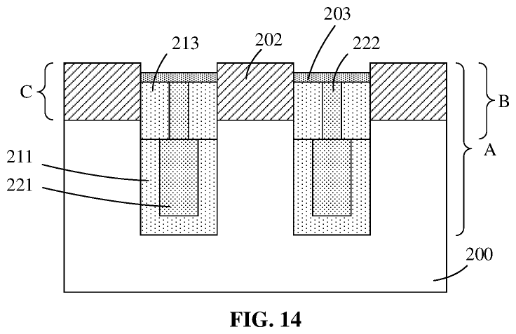

Referring to FIG. 14, a protective layer 203 for covering the top surface of the second gate oxide layer 213 and the top surface of the second gate conductive layer 222 is formed.

A chemical vapor deposition process is used to form the protective layer 203, so that the protective layer 203 may be rapidly formed, and the formed protective layer 203 tightly covers without forming any gap exposing the second gate oxide layer 213 or the second gate conductive layer 222. In other embodiments, an atomic layer deposition process may also be used to form the protective layer.

The top of the groove is higher than the top of the protective layer 203, which can prevent the protective layer 103 from contacting with the bit line contact layer and thus affecting the performance of the semiconductor structure as a bit line contact layer needs to be formed on the top of the substrate 200 subsequently.

The material of the protective layer 203 is silicon nitride, which has an insulating effect.

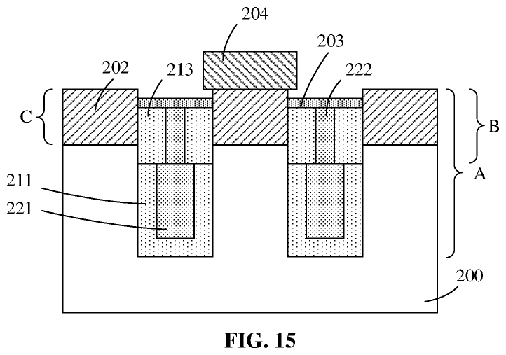

Referring to FIG. 15, a bit line contact layer 204 is formed on the top surface of the substrate 200 between adjacent protective layers 203, in which the bottom of the bit line contact layer 204 keeps away from the top surfaces of the protective layers 203.

In the embodiment of the present disclosure, the second gate conductive layer is formed firstly, and then the second gate oxide layer is formed. When the material of the first gate oxide layer and the material of the second gate oxide layer are the same, the thickness of the second gate oxide layer is greater than the thickness of the first gate oxide layer. Compared with the method in which the second gate oxide layer is firstly formed and then the second gate conductive layer is filled, the method of the embodiment of the present disclosure is more beneficial to avoid forming a gap in the entire interior of the gate, so as to improve the performance of the semiconductor structure.

Embodiments of the present disclosure provide a semiconductor structure formed on the basis of the method for forming a semiconductor structure of the above embodiments. The semiconductor structure provided by the embodiments of the present disclosure is described in detail below in combination with the drawings.

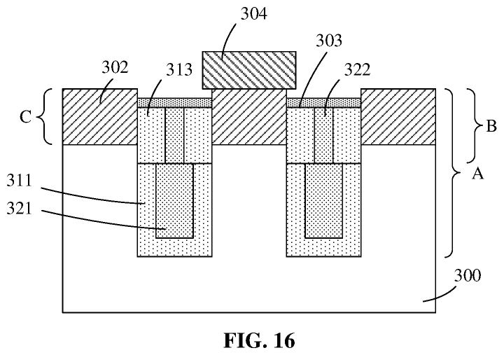

FIG. 16 is a structure schematic diagram of a semiconductor structure provided by an embodiment of the disclosure.

Referring to FIG. 16, it includes a substrate 300, a first gate oxide layer 311, a first gate conductive layer 321, a second gate oxide layer 313, and a second gate conductive layer 322. Grooves (not shown) and doped areas 302 are provided in the substrate 300, in which the grooves have a first depth A, and the doped areas 302 have a third depth C. The first gate oxide layer 311 is provided on side walls and a bottom surface of a groove, and the first gate conductive layer 321 is provided on a surface of the first gate oxide layer 311, in which the first gate oxide layer 311 and the first gate conductive layer 321 have a second depth B, in which the second depth B is less than the first depth A. The second gate oxide layer 313 is located on the side walls, exposed by the first gate oxide layer 311, of the groove, in which in a direction perpendicular to the side wall of the groove, the equivalent gate oxide thickness of the second gate oxide layer 313 is greater than the equivalent gate oxide thickness of the first gate oxide layer 311. The second gate conductive layer 322 fills up the recess surrounded by the second gate oxide layer 313 and the first gate conductive layer 321.

The doped areas 302 may be N-type doped areas or P-type doped areas. In the embodiment of the present disclosure, when the doped areas 302 are N-type doped areas, they are doped with N-type ions, and the substrate 300 is doped with P-type ions. In other embodiments, when the doped areas are P-type doped areas, they are doped with P-type ions, and the substrate is doped with N-type ions.

The doped area 302 located on one side of the groove serves as a source, and the doped area 302 located on the other side of the groove serves as a drain. The material of the substrate 300 is a semiconductor material. In the embodiment of the present disclosure, the material of the substrate 300 is silicon. In other embodiments, the substrate may also be a germanium substrate, a silicon germanium substrate, a silicon carbide substrate, or a silicon-on-insulator substrate.

The groove provides a process basis for forming the gate subsequently, which is subsequently formed in the groove.

The groove has the first depth A, and the doped area 302 has the third depth C. Generally, the third depth C is less than the first depth A. The first depth A is the distance between the bottom of the groove and the top surface of the substrate 300, and the third depth C is the distance between the bottom surface of the doped area 302 and the top surface of the substrate 300.

In some embodiments, the first depth A may be 300 nm-800 nm, for example, 400 nm, 500 nm or 600 nm. The third depth C may be 100 nm-200 nm, for example, 120 nm, 150 nm or 180 nm.

The first gate oxide layer 311 and the first gate conductive layer 321 have the second depth B, in which the second depth B is the distance between the top surface of the first gate oxide layer 311 or the top surface of the first gate conductive layer 321 and the top surface of the substrate 300. In some embodiments, the second depth B may be 102 nm-230 nm.

The second depth B is less than the first depth A, and the second depth B is greater than or equal to the third depth C. It is equivalent to that in the horizontal direction, the bottom surface of the doped area 302 is higher than the top surface of the first gate oxide layer 311, or the bottom surface of the doped area 302 is flush with the top surface of the first gate oxide layer 311, so that the side wall of the doped area 302 and the side wall of the first gate oxide layer 311 area are not overlapped. Therefore, when the gate is turned on, an enhanced electric field is generated in the area due to a depletion region generated in the gate, which will not affect the doped area 302 after penetrating the first gate oxide layer 311, and thus inter-band tunneling will not be formed between the doped area 302 and the first gate conductive layer 321.

The difference between the second depth B and the third depth C may be 2 nm-30 nm, for example, 5 nm, 10 nm or 20 nm. In this way, the side wall of the doped area 302 and the side wall of the first gate oxide layer 311 are not overlapped. When the gate is turned on, the range of the enhanced electric field generated in the area due to the depletion region generated in the gate does not include an area in which the doped area 302 is located, so the enhanced electric field will not affect the doped area 302.

The material of the first gate oxide layer 311 may be silicon oxide or a high-dielectric material. The high-dielectric material includes ferroelectric ceramic materials, barium titanate-based materials, or lead titanate-based material. The high-dielectric material refers to a material of which a relative dielectric constant is greater than that of silicon oxide, namely a high-k material.

The material of the first gate conductive layer 321 is metal. In the embodiment of the present disclosure, the material of the first gate conductive layer 321 may be tungsten. In other embodiments, the material of the first gate conductive layer may also be copper, aluminum, gold or silver and the like.

In the direction perpendicular to the side wall of the groove, the thickness of the first gate oxide layer 311 is 3 nm-10 nm, and it may be 5 nm, 7 nm or 9 nm.

In the direction perpendicular to the side wall of the groove, the thickness of the first gate conductive layer 321 is 30 nm-150 nm, for example, 60 nm, 90 nm or 120 nm.

In the embodiment of the present disclosure, in the direction perpendicular to the side wall of the groove, the equivalent gate oxide thickness of the second gate oxide layer 313 is greater than the equivalent gate oxide thickness of the first gate oxide layer 311.

Because the second depth B is greater than or equal to the third depth C, in the horizontal direction, the doped area 302 is directly opposite to the second gate oxide layer 313. When the gate is turned on, an enhanced electric field is generated in the area due to a depletion region generated in the gate, an effective area of which includes an area in which the second gate oxide layer 313 is located. Moreover, because the equivalent gate oxide thickness of the second gate oxide layer 313 is relatively thick, the band bending caused by the enhanced electric field is not easy to cause the inter-band tunneling between the gate and the drain. In this case, there is no tunnel for a minority carrier moved in the gate to enter the drain, which is beneficial to reduce a risk of generating the GIDL, thereby improve the performance of the semiconductor structure.

In the embodiment of the present disclosure, the material of the second gate oxide layer 313 may be silicon oxide or a high-dielectric material. The high-dielectric material includes ferroelectric ceramic materials, barium titanate-based materials, or lead titanate-based materials.

In the embodiment of the present disclosure, the material of the second gate oxide layer 313 is the same as the material of the first gate oxide layer 311. In the direction perpendicular to the side wall of the groove, the thickness of the second gate oxide layer 313 is greater than the thickness of the first gate oxide layer 311.

Because the thickness of the second gate oxide layer 313 is greater than the thickness of the first gate oxide layer 311, the second gate oxide layer 313 is at least partially located on a top surface of the first gate conductive layer 321.

In other embodiments, the material of the second gate oxide layer is different from the material of the first gate oxide layer, and the dielectric constant of the material of the second gate oxide layer is greater than that of the material of the first gate oxide layer.

In the embodiment of the present disclosure, in the direction perpendicular to the side wall of the groove 301, the thickness of the second gate oxide layer 313 is 5 nm-20 nm, for example, 9 nm, 14 nm or 18 nm.

In a direction parallel to the side wall of the groove 301, the thickness of the second gate oxide layer 313 is 2 nm-20 nm, for example, 6 nm, 10 nm or 15 nm.

The third depth C is 2 nm-20 nm, for example 5 nm, 10 nm or 15 nm, greater than the distance between the top of the second gate oxide layer 313 and the top of the groove.

In the embodiment of the present disclosure, the material of the second gate conductive layer 322 is polysilicon, a dielectric constant of which is greater than that of metal. The use of polysilicon as the second gate conductive layer 322 is more beneficial to regulate a gate voltage. In other embodiments, the material of the second gate conductive layer is metal.

In the embodiment of the present disclosure, in the direction perpendicular to the side wall of the groove, the thickness of the second gate conductive layer 322 is 5 nm-100 nm, for example, 20 nm, 40 nm or 6 nm.

Because in the direction perpendicular to the side wall of the groove, the first gate oxide layer 311 and the first gate conductive layer 321 completely fill the groove, and the second gate oxide layer 313 and the second gate conductive layer 322 also completely fill the groove, the total thickness of the first gate oxide layer 311 and the first gate conductive layer 321 is the same as the total thickness of the second gate oxide layer 313 and the second gate conductive layer 322.

A protective layer 303 covers the top surface of the second gate oxide layer 313 and the top surface of the second gate conductive layer 322.

The top of the groove is higher than a top of the protective layer 303, which can prevent the protective layer 103 from contacting with the bit line contact layer and thus affecting the performance of the semiconductor structure as a bit line contact layer needs to be subsequently formed on the top portion of the substrate 300.

The material of the protective layer 303 is silicon nitride, which has an insulating effect.

A bit line contact layer 304 is located on the top surface of the substrate 300 between adjacent protective layers 303, and the bottom of the bit line contact layer 304 keeps away from the top surfaces of the protective layers 303.

In the semiconductor structure provided by the embodiments of the present disclosure, the gate oxide layer includes two layers, in which the equivalent gate oxide thickness of the second gate oxide layer is greater than the equivalent gate oxide thickness of the first gate oxide layer, and the second depth of the first gate oxide layer is greater than or equal to the third depth of the doped area. When the gate is turned on, an enhanced electric field is generated in the area due to a depletion region generated in the gate, the effective area of which is located in the area in which the second gate oxide layer is located, and thus the band bending caused by which is not easy to cause the inter-band tunneling between the gate and the drain because the equivalent gate oxide thickness of the second gate oxide layer is relatively thick, and in the horizontal direction, the doped area is directly opposite to the second gate oxide layer. In this case, there is no tunnel for the minority carrier moved in the gate to enter the drain, which is beneficial to reduce the risk of generating the GIDL, thereby improving the performance of the semiconductor structure.

A person of ordinary skill in the art may understand that the above implementation modes are some embodiments for implementing the present disclosure, to which in actual applications, various changes may be made in forms and details without departing from the spirit and scope of the present disclosure. Any persons skilled in the art may make their own changes and modifications without departing from the spirit and scope of the present disclosure. Therefore, a scope of protection of the present disclosure shall be subject to a scope defined by the claims.

1. A method for forming a semiconductor structure, comprising:
providing a substrate, wherein grooves are provided in the substrate, wherein the grooves have a first depth;
forming a first gate oxide layer on side walls and a bottom surface of a groove, and forming a first gate conductive layer on a surface of the first gate oxide layer, wherein the first gate oxide layer and the first gate conductive layer have a second depth, wherein the second depth is less than the first depth;
forming a second gate oxide layer on surfaces of the groove that are not covered by the first gate oxide layer, wherein in a direction perpendicular to a side wall of the groove, an equivalent gate oxide thickness of the second gate oxide layer is greater than an equivalent gate oxide thickness of the first gate oxide layer; and
forming a second gate conductive layer, wherein the second gate conductive layer fills up a recess surrounded by the second gate oxide layer and the first gate conductive layer.

2. The method for forming a semiconductor structure of claim 1, wherein doped areas are further provided in the substrate, wherein the doped areas are located on two sides of a groove, and the doped areas have a third depth, the second depth being greater than or equal to the third depth.

3. The method for forming a semiconductor structure of claim 1, wherein materials of the first gate oxide layer and the second gate oxide layer are the same, and in the direction perpendicular to the side wall of the groove, a thickness of the second gate oxide layer is greater than a thickness of the first gate oxide layer.

4. The method for forming a semiconductor structure of claim 1, wherein the step of forming the second gate oxide layer comprises: forming an initial second gate oxide layer on entire side walls, exposed by the first gate oxide layer, of the groove, and removing a part of the initial second gate oxide layer close to a top of the groove, so as to form the second gate oxide layer.

5. The method for forming a semiconductor structure of claim 4, wherein a thermal oxidation process is used to form the initial second gate oxide layer.

6. The method for forming a semiconductor structure of claim 1, wherein the step of forming the second gate oxide layer and the second gate conductive layer comprises: after forming the first gate conductive layer, forming an initial second gate conductive layer filling up the groove, and removing a part of the initial second gate conductive layer located on the side walls of the groove to form gaps, wherein in the direction perpendicular to the side wall of the groove, a thickness of remaining initial second gate conductive layer is less than a thickness of the first gate conductive layer, and the remaining initial second gate conductive layer is the second gate conductive layer; and forming the second gate oxide layer filling up the gaps.

7. The method for forming a semiconductor structure of claim 6, wherein a chemical vapor deposition process is used to form the second gate oxide layer filling up the gaps.

8. The method for forming a semiconductor structure of claim 1, wherein the formed second gate oxide layer is at least partially located on a top surface of the first gate conductive layer.

9. The method for forming a semiconductor structure of claim 1, further comprising: forming a protective layer, wherein the protective layer is located on top surfaces of the second gate oxide layer and the second gate conductive layer.

10. The method for forming a semiconductor structure of claim 9, further comprising: after forming the protective layer, forming a bit line contact layer on a top layer of the substrate between adjacent protective layers, wherein a bottom of the bit line contact layer keeps away from top surfaces of the protective layers.

11. A semiconductor structure, comprising:
a substrate, wherein grooves are provided in the substrate, and the grooves have a first depth;
a first gate oxide layer provided on side walls and a bottom surface of a groove, and a first gate conductive layer provided on a surface of the first gate oxide layer, wherein the first gate oxide layer and the first gate conductive layer have a second depth, and the second depth is less than the first depth;
a second gate oxide layer, located on the side walls, exposed by the first gate oxide layer, of the groove, wherein in a direction perpendicular to a side wall of the groove, and an equivalent gate oxide thickness of the second gate oxide layer is greater than an equivalent gate oxide thickness of the first gate oxide layer; and
a second gate conductive layer, filling up a recess surrounded by the second gate oxide layer and the first gate conductive layer.

12. The semiconductor structure of claim 11, wherein materials of the first gate oxide layer and the second gate oxide layer are the same.

13. The semiconductor structure of claim 11, wherein a dielectric constant of second gate oxide layer material is greater than a dielectric constant of first gate oxide layer material.

14. The semiconductor structure of claim 11, wherein a material of the first gate conductive layer is metal, and a material of the second gate conductive layer is polysilicon.

15. The semiconductor structure of claim 11, further comprising: a protective layer, wherein the protective layer covers a top surface of the first gate oxide layer and a top surface of the second gate conductive layer.
